(19) United States
(12) Patent Application Publication
(10) Pub. No.: US 2014/0272653 A1
(43) Pub. Date: Sep. 18, 2014

(54) Flow Battery System and Method of SOC Determination

(71) Applicants: Robert Bosch GmbH, Stuttgart (DE); Bosch Energy Storage Solutions LLC, Farmington Hills, MI (US)

(72) Inventors: Nalin Chaturvedi, Sunnyvale, CA (US); Ashish Samuel Krupadanam, Cupertino, CA (US); Maksim Subbotin, Menlo Park, CA (US); Jasim Ahmed, Mountain View, CA (US)

(73) Assignees: Robert Bosch GmbH, Stuttgart (DE); Bosch Energy Storage Solutions LLC, Farmington Hills, MI (US)

(21) Appl. No.: 14/203,373

(22) Filed: Mar. 10, 2014

Related U.S. Application Data
(60) Provisional application No. 61/782,195, filed on Mar. 14, 2013.

(51) Int. Cl. H01M 8/04; G01R 31/36

(52) U.S. Cl. CPC H01M 8/04537; H01M 8/04552; H01M 8/04582; G01R 31/3624
USPC 429/431; 702/63

(57) ABSTRACT

A flow battery system includes a flow cell, a reservoir including an aqueous electrolyte, a memory in which command instructions are stored, a model of the flow cell stored within the memory, and a processor configured to execute the command instructions to obtain a current signal and a voltage signal, estimate a state of charge (SOC) of the flow cell using the obtained current signal, compute a model voltage of the flow cell using the obtained current signal, the obtained voltage signal, and the model, compare the model voltage with the obtained voltage signal, calculate a voltage error based upon the comparison of the model voltage with the obtained voltage signal, and correct the estimated SOC based upon the voltage error.

This application claims the benefit of U.S. Provisional Application No. 61/782,195 filed Mar. 14, 2013, the entirety of which is incorporated herein by reference.

### FIELD

This disclosure relates to batteries, and more particularly, to flow battery system and method thereof.

### BACKGROUND

A flow battery is a form of rechargeable battery in which electrolyte containing one or more dissolved electro-active species flows through an electrochemical cell that converts chemical energy directly to electricity. The electrolyte is stored externally, generally in tanks, and is pumped through the cell (or cells) of the reactor. Due to the fact that conversion takes place in the cell of the battery, while the electrolyte with the active species is stored in individual tank or tanks, flow battery systems allow separation between power that can be provided or absorbed by the battery and the amount of energy that can be stored. Power is defined by the properties and the dimensions of the cell, while the amount of energy is defined by capacity of the tanks storing the active ingredients.

During a charge or discharge process the active species react in the cell and are extracted from or introduced back into the electrolyte solution. Depending on architecture of the battery, the active species can be concentrated on the electrodes of the electrochemical cell during, for example, the battery charge process. In either case, the resulting change in concentration of active species results in a change in the observed impedance of the cell for a given operational condition.

Flow batteries are a promising technology for storage of electrical energy in stationary applications such as grid-scale renewable bulk energy storage systems, rail regeneration storage systems, and grid-scale frequency regulation systems. These applications require large storage capacities and hence only cost-effective technologies are considered as sustainable long-term solutions.

Because large scale storage systems are stationary, restrictions on dimensions and weight are less strenuous than for mobile systems. Efficiency requirements are also less strict than those for mobile applications since in most situations the stationary systems provide storage for electrical energy which otherwise would be dissipated (in the case of rail regeneration), not generated due to the lack of load in off-peak hours (in the case with wind and solar) or generated with low-efficiency sources such as oil or gas peaker plants (in the case of frequency and peak regulation).

Control of flow batteries requires knowledge of the flow rate and State of Charge (SOC). Together, flow rate and SOC determine the concentration and availability of reactants at the electrodes and the current that can be drawn from the cell for the best efficiency and within safe limits. The SOC is thus used to determine how much energy the battery can store or deliver. This can be used to plan the usage of the battery in a device or within a power supply system. It may also determine the power that the battery can produce.

Estimation of SOC of electro-chemical batteries including flow batteries is considered as one of the most challenging and important technical problems that has to be solved in order to guarantee efficient and reliable operation of an energy storage system. Accurate estimation of SOC of a battery is required for evaluation of the amount of energy that is stored in the battery or can be accumulated by the battery. More importantly SOC is required for correct definition of charge and discharge parameters of the battery such as electric currents and voltages that can be applied to and expected from the battery. These parameters define safe operation margins for the battery and affect its instantaneous and long-term performance and its life span. Accurate estimation of SOC allows optimal operation of a given electrochemical battery and, as a result, provides the most efficient technical and economical utilization of individual battery cells and combined battery systems.

A need exists for a flow battery system which allows for simple and accurate SOC determination.

### SUMMARY

In flow batteries, a change in SOC can result a change in the open circuit voltage (OCV) or a change in the observed internal impedance of a flow battery causing the measured output voltage to vary. In this disclosure, a model is used to estimate SOC recursively. The advantage of observing SOC using this technique over direct or indirect SOC measurement techniques or table-based SOC estimation techniques is that the disclosed method is more robust to noise. Furthermore, depending on the design, the observer can reject ‘bad’ data during transients. The method also applies to any generic flow battery.

In one embodiment, the state of charge (SOC) of a flow battery is estimated using voltage and current measurements, and/or other additional measurements (including but not limited to) flow rate, pressure, and temperature. The disclosed method applies to any generic flow battery which are divided into three classes. The first technique relies on the fact that the internal impedance of a flow battery varies with the SOC of the flow battery. The second technique relies on open circuit voltage (OCV) variation with SOC without significant impedance change. The third class applies to a generic flow battery and carefully estimates impacts of change in OCV due to SOC and change in impedance due to SOC to detect the true SOC. The disclosed method exploits these various facts to design an SOC estimator which uses voltage as a model output, current as a model input, and possibly other measurements such as flow-rate, temperature, and pressure as model inputs. Given the measured inputs, the model output can be computed, i.e. the output voltage of the stack. This computed output voltage is then compared with the measured voltage and a voltage error is calculated. This voltage error is used to correct the current estimate of the SOC of the flow battery that is calculated via coulomb counting using various observer design techniques.

In one embodiment, a flow battery system includes a flow cell, a reservoir including an aqueous electrolyte, a first sensor configured to generate a current signal indicative of an amplitude of a current passing into or out of the flow cell, a second sensor configured to generate a voltage signal indicative of an output voltage across the flow cell, a memory in which command instructions are stored, a model of the flow cell stored within the memory, and a processor configured to execute the command instructions to obtain the current signal and the voltage signal, estimate a state of charge (SOC) of the flow cell using the obtained current signal, compute a model voltage of the flow cell using the obtained current signal, the obtained voltage signal, and the model, compare the model voltage with the obtained voltage signal, calculate a voltage error based upon the comparison of the model voltage with the obtained voltage signal, and correct the estimated SOC based upon the voltage error.

In another embodiment, a method of correcting an estimated state of charge (SOC) of a flow battery system includes obtaining a current signal indicative of an amplitude of a current passing into or out of the flow cell, obtaining a voltage signal indicative of an output voltage across the flow cell, estimating with a processor a state of charge (SOC) of the flow cell using the obtained current signal, computing with the processor a model voltage of the flow cell using the obtained current signal and the obtained voltage signal using a model stored in a memory, comparing with the processor the model voltage and the obtained voltage signal, calculating with the processor a voltage error based upon the comparison of the model voltage with the obtained voltage signal, and correcting with the processor the estimated SOC based upon the voltage error.

### BRIEF DESCRIPTION OF THE DRAWINGS

FIG. 1 depicts a schematic of a flow battery system in accordance with principles of the present disclosure;

FIG. 2 depicts a schematic of the battery management system for the battery system of FIG. 1;

FIG. 3 depicts Gamma functions for a flow-battery;

FIG. 4 depicts a bulk concentrations as a function of SOC;

FIG. 5 depicts an equivalent circuit model for flow-battery; and

FIG. 6 depicts a process controlled by the control system of FIG. 2 which is various embodiments is used to determine the SOC of the flow battery system of FIG. 1.

### DESCRIPTION

For the purposes of promoting an understanding of the principles of the disclosure, reference will now be made to the embodiments illustrated in the drawings and described in the following written specification. It is understood that no limitation to the scope of the disclosure is thereby intended. It is further understood that the present disclosure includes any alterations and modifications to the illustrated embodiments and includes further applications of the principles of the disclosure as would normally occur to one skilled in the art to which this disclosure pertains.

FIG. 1 depicts a schematic of a battery system 100. In one embodiment, the battery system 100 is used to power a vehicle motor 102 through a bi-directional inverter 104. The battery system 100 includes a cell or cell stack 106 which includes a negative electrode 108, a separator 110, and a positive electrode 112. The separator 110 is a dense solid electrolyte that transports metal ions but is a barrier to electrons, liquid electrolyte, and oxygen or other species.

The positive electrode 112 is a porous matrix of electronically conducting material defining a continuous network of passages. The positive electrode 112 includes carbon or some other electronically conductive material that provides a continuous path for electrons, optionally catalyst materials (especially for oxygen reduction and evolution in aqueous chemistries), and optionally binder material. The electrode is porous, with electrolyte 160 in the pores and, in some embodiments, includes gas channels. The conductive material is contacted to an electronically conductive gas-diffusion layer (e.g., from carbon fiber) at the back side (opposite side from the separator 110). The gas-diffusion layer (GDL) is open to oxygen or air (from the environment or from an oxygen tank).

The positive electrode 112 is in fluid connection with a reservoir 118 through a header 120. The reservoir 118 includes two outlets 122 and 124. The outlet 122 is connected to the suction side of a centrifugal pump 126 by a discharge header 128. A discharge header control valve 130 is located in the discharge header 128. In one embodiment (not shown), the discharge header control valve 130 is located in an outlet header 132 which connects the centrifugal pump 126 to a supply header 134.

The outlet 124 is connected to the suction side of a peristaltic pump 140 by a charging header 142. A charging header control valve 144 is located in the charging header 142. An outlet header 146 connects the pump 140 to the supply header 134. A mixing control valve 148 is located in the outlet header 146.

The supply header 134 is in fluid communication with the positive electrode 112. A mixer 150 and a heat exchanger portion 152 of a temperature control unit 154 are operably positioned within the supply header 134. Additionally, an exchanger portion 156 of a temperature control unit 158 is operably positioned within the reservoir 118.

In the embodiment of FIG. 6, the reservoir 118, positive electrode 112, and headers 128, 132, 134, 142, and 146 are substantially filled with an aqueous electrolyte.

In one embodiment, the battery system 100 is a metal halide flow battery wherein “M” is the active metal and “X” is the halogen species. Operation of the battery system 100, is controlled by a control system 200 shown in FIG. 2. The control system 200 includes a processor 202 and a memory 204 in which command instructions are stored. The processor 202 is operably connected to the various components including the pumps 126 and 140, discharge header control valve 130, charging header control valve 144, mixing control valve 148, and sensors (not shown) such as coulomb counters, temperature sensors, etc.

The battery management system 200 further includes a model 206 of the battery system 100 stored in the memory 204. In different embodiments, the model varies from a very simple equivalent circuit model to very complex electrochemical-based model. The more accurate the model, the better is the accuracy of the disclosed method to compute SOC.

Denoting ‘u’ as the input current, an embodiment of the electrochemical model 200 for the output voltage for the flow battery of FIG. 1 is given by

$${V}_{cell} = {U}_{OCV} + k \cdot ln ( \frac{{c}_{{X}^{-}}^{bulk}}{{c}_{{X}^{-}}^{ref}} ) + u ( \frac{{l}_{+}}{{κ}_{+}} + \frac{{l}_{-} ( x )}{{κ}_{-}} ) + \frac{2 RT}{F} ln ( {( \frac{{c}_{{X}^{-}}^{bulk}}{{c}_{{X}^{-}}} )}^{{β}_{+}^{trans}} {( \frac{{c}_{{M}^{+}}^{bulk}}{{c}_{{M}^{+}}} )}^{{β}_{-}^{trans}} ) + \frac{2 RT}{F} [ {sinh}^{- 1} ( \frac{u}{{k}_{+} {c}_{X}^{1 / 2} {c}_{{X}^{-}}^{1 / 2}} ) + {sinh}^{- 1} ( \frac{u}{{k}_{-} {c}_{{M}^{+}}^{1 / 2}} ) ] + u ( {R}_{-} + {R}_{+} + {R}_{contact} ) , \qquad 1$$

where, the first term is a constant open circuit voltage (OCV) measured at a reference concentration c_{X-}^{ref}, the second term corrects for the OCV due to a changing state-of-charge (SOC), and the remaining terms correspond to various impedances that arise due to an applied current u. The variable ‘T’ is the temperature of the electrolyte. The concentrations at the reaction surface in equation (1) depend on the bulk concentrations in the flow by

$$\begin{matrix}{c}_{{X}^{-}} = {c}_{{X}^{-}}^{bulk} ( \frac{s {τ}_{{X}^{-}} + {γ}_{{X}^{-}} ( u )}{s {τ}_{{X}^{-}} + 1} ) , & 2 \\ {c}_{X} = {c}_{X}^{bulk} ( \frac{s {τ}_{X} + {γ}_{X} ( u )}{s {τ}_{X} + 1} ) , & 3 \\ {c}_{{M}^{+}} = {c}_{{M}^{+}}^{bulk} ( \frac{s {τ}_{{M}^{+}} + {γ}_{{M}^{+}} ( u )}{s {τ}_{{M}^{+}} + 1} ) , & 4\end{matrix}$$

where the gamma-function is a monotonic function that satisfies

γ_{(•)}(0)=1 5

The Gamma-functions can vary widely. One embodiment of a flow-battery includes a form that appears qualitatively as in FIG. 3.

Finally, the bulk concentrations in flow given in equations (2)-(4) are described in terms of the bulk concentrations in the reservoir and the flow-rate ‘N’ as

$$\begin{matrix}{c}_{{X}^{-}}^{bulk} = ( 1 - \frac{u / 2 FN}{{c}_{{X}^{-}}^{bulk , res} ( soc )} ) {c}_{{X}^{-}}^{bulk , res} ( x ) , & 6 \\ {c}_{X}^{bulk} = ( 1 + \frac{u / 2 FN}{{c}_{X}^{bulk , res} ( soc )} ) {c}_{X}^{bulk , res} ( x ) , & 7 \\ {c}_{{M}^{+}}^{bulk} = ( 1 - \frac{u / 2 FN}{{c}_{{M}^{+}}^{bulk , res} ( soc )} ) {c}_{{M}^{+}}^{bulk , res} ( x ) , & 8 \\ \frac{d x}{d t} = η ( u , T ) \frac{u}{{C}_{0}} , & 9\end{matrix}$$

where the bulk concentrations are a monotonic function of the SOC ‘x’, ‘C₀’ is the nominal capacity, ‘F’ is Faraday's constant, and η is the coulombic efficiency. Among different examples, one embodiment of the bulk concentration function is as shown in FIG. 4.

The model given by equations (1)-(9) is a complex model that describes the behavior of a generic flow-battery. The model (1)-(9) is too complex to design state-of-charge algorithms. To alleviate this problem, one can for build an equivalent circuit model from (1)-(9) given as

$$\begin{matrix}{V}_{cell} = {U}_{ocv} + k ln ( \frac{x}{{x}_{ref}} ) + {uR}_{0} ( x , u , T , N ) + {i}_{1} {R}_{1} ( x , {i}_{1} , T , N ) , & 10 \\ \frac{d {i}_{1}}{d t} = \frac{( u - {i}_{1} )}{{R}_{1} {C}_{1}} , & 11\end{matrix}$$

where R₀, R₁, and C₁ are impedances modeled as shown in FIG. 5. These impedances are functions of state-of-charge, current, temperature, and flow-rate, respectively.

In FIG. 5, The capacitor C₁ is the capacitance due to, among other factors, multi-polar electrode structure and the double layer capacitance. Note that for a DC operation, impedance due to C₁ can be assumed infinite, and hence the total impedance is given by Rₜₒₜ=R₀+R₁. The impedance Rₜₒₜ is thus a function of concentration, u, x, N, T. Thus, in the case where the current u does not vary very quickly, one can neglect the dynamics in (11) due to C₁ and approximate (10) further as

$${V}_{cell} = {U}_{ocv} + k ln ( \frac{x}{{x}_{ref}} ) + {uR}_{tot} ( x , u , T , N ) , \qquad 12$$

where x_{ref} is some reference SOC. Thus, the reduced approximate model is given by equations (9) and (12). The second term in equation (12) indicates the change in OCV for the actual concentration of the active species in the reservoir of the flow battery, and the third term lumps all kinetic, diffusion and ohmic losses into an impedance term.

Depending on the type of flow-battery, one has to apply different strategies for SOC estimation. We will next classify all flow batteries into three categories and present a strategy to estimate SOC for each type.

### Class 1: ‘Flat’ Open Circuit Voltage Flow-Battery

In a “Flat” open circuit voltage flow battery, the open circuit voltage (OCV) does not change significantly with respect to SOC. Thus, one can model the flow-battery with equations (9) and (12), where one identifies the parameter k≈0. Thus, the model is reduced to

$$\begin{matrix}\frac{d x}{d t} = η ( u , T ) \frac{u}{{C}_{0}} , & 13 \\ {V}_{cell} = {U}_{ocv} + {uR}_{tot} ( x , u , T , N ) . & 14\end{matrix}$$

Now since the impedance Rₜₒₜ is a function of SOC (x), current (u), temperature (T), and flow-rate (N), one can invert this model for given impedance, current, temperature and flow-rate as

x=ƒ(Rₜₒₜ,u,T,N) 15

where ƒ is now a known function from the model and Rₜₒₜ=∥(V_{cell}−U_{OCV})/u∥. While one can use this directly for SOC estimation, the estimates will be very sensitive to noise and model uncertainties. Also, when current ‘u’ is zero, the method may fail to give a reliable estimate due to division-by-zero. Thus a more robust way of implementing this solution is to estimate Rₜₒₜ using a least-squares or other recurrence-based method such as gradient estimator. In once such an embodiment, we define \hat{R}ₜₒₜ as the estimate of the total resistance. Then, the online estimation of Rₜₒₜ is defined by

$$\begin{matrix}\frac{d {\hat{R}}_{tot}}{d t} = - pu ( {\hat{V}}_{cell} - {U}_{OCV} + u {\hat{R}}_{tot} ) , & 16 \\ \frac{d p}{d t} = β p - {p}^{2} - {p}^{2} {u}^{2} . & 17\end{matrix}$$

where \hat{V}_{cell} is the measured voltage, U_{OCV} is the known open-circuit voltage and p is a positive number. The SOC estimate is then defined as

\hat{x}=ƒ(\hat{R}ₜₒₜ,u,T,N) 18

Thus, for “Flat” open circuit voltage flow-batteries, the strategy to estimate SOC is to use equations (16)-(18).

### Class 2: ‘Flat’ Impedance Characteristic Flow-Battery

In a “Flat” impedance characteristic flow-battery, the impedance does not vary significantly with respect to SOC. For such a case, the model is given by equations (9) and (12), where Rₜₒₜ is not a function of x anymore. Then one can estimate SOC indirectly by observing the error between measured voltage and model voltage, and designing a standard observer (eg. Kalman Filter, Luenberger observer, etc.). Thus, the estimator is directly defined for the SOC ‘x’ in contrast to class 1, where the estimator was defined for the impedance. An embodiment of such an observer is given as

$$\frac{d \hat{x}}{d t} = η ( u , T ) \frac{u}{{C}_{0}} + L ( {V}_{cell} - {\hat{V}}_{cell} ) . \qquad 19$$

where L>0 is a constant gain, \hat{x} represents the estimated SOC and \hat{V}_{cell} is the model output.

### Class 3: Generic Flow-Battery Model

In the most general class of flow-battery models, all parameters of the battery model can vary with SOC. Thus, both OCV and the impedance are functions of SOC, in addition to other variables such as current u, temperature T, flow-rate N, etc. Now for a flow-battery, with everything else constant, if SOC increases then Rₜₒₜ monotonically decreases. This can be mathematically expressed as for every x₁≠x₂, there exists M₁, M₂>0 such that

−M₁(x₁−x₂)²>[Rₜₒₜ(x₁,u,T,N)−Rₜₒₜ(x₂,u,T,N)](x₁−x₂)>−M₂(x₁−x₂)² 20

Additionally note that since the OCV is not flat, k>0. Then, an embodiment of the estimator to estimate SOC for a generic model of flow-battery is as follows.

$$\begin{matrix}\frac{d \hat{x}}{d t} = η ( u , T ) \frac{u}{{C}_{0}} + L ( {V}_{cell} - {\hat{V}}_{cell} ) . & 21 \\ L = \{ \begin{matrix}0 if u > 0 , \\ {L}_{0} if u \leq 0 ,\end{matrix} & 22\end{matrix}$$

and L₀>0. To show that this estimator indeed estimates SOC correctly, we investigate the error dynamics given by the nonlinear system

$$\frac{d \hat{x}}{d t} = - Lk ln ( 1 + \frac{\tilde{x}}{\hat{x}} ) - Lu [ {R}_{tot} ( \hat{x} + \tilde{x} , u , T , N ) - {R}_{tot} ( \hat{x} , u , T , N ) ] . \qquad 23$$

It is easy to show that the error dynamics identified in equation (23) is stable. To see this, we calculate the derivative of the Lyapunov function V(x)=x²/2 given as

$$\frac{d V}{d t} = - Lk ln ( 1 + \frac{\tilde{x}}{\hat{x}} ) \tilde{x} - Lu \tilde{x} [ {R}_{tot} ( \hat{x} + \tilde{x} , u , T , N ) - {R}_{tot} ( \hat{x} , u , T , N ) ] . \qquad 24$$

Clearly the derivative is zero for u>0. For u≦0,

$$\begin{matrix}\frac{d V}{d t} = - {L}_{0} k ln ( 1 + \frac{\tilde{x}}{\hat{x}} ) \tilde{x} + {L}_{0} ‖ u ‖ \tilde{x} [ {R}_{tot} ( \hat{x} + \tilde{x} , u , T , N ) - \\ {R}_{tot} ( \hat{x} , u , T , N ) ] , \\ \leq - {L}_{0} k ln ( 1 + \frac{\tilde{x}}{\hat{x}} ) \tilde{x} - {L}_{0} ‖ u ‖ {M}_{1} {\tilde{x}}^{2} , \\ < 0\end{matrix} \qquad 25$$

The last step follows since for \tilde{x}>0,

$$ln ( 1 + \frac{\tilde{x}}{x} ) \tilde{x} > 0.$$

Suppose \tilde{x}<0. Then

$$‖ \frac{\tilde{x}}{\hat{x}} ‖ < 1.$$

### Hence,

$$ln ( 1 + \frac{\tilde{x}}{\hat{x}} ) \tilde{x} = {( \frac{\tilde{x}}{\hat{x}} )}^{2} ( 1 - \frac{1}{2} \frac{\tilde{x}}{\hat{x}} ) \hat{x} + {( \frac{\tilde{x}}{\hat{x}} )}^{4} ( \frac{1}{3} - \frac{1}{4} \frac{\tilde{x}}{\hat{x}} ) \hat{x} + {( \frac{\tilde{x}}{\hat{x}} )}^{6} ( \frac{1}{5} - \frac{1}{6} \frac{\tilde{x}}{\hat{x}} ) \hat{x} + … > 0. \qquad 26$$

Hence the strategy/algorithm given by (21) and (22) converges for a large class of generic flow batteries.

FIG. 6 depicts a flow chart for application of the desired model depending upon the class of flow battery.

While the disclosure has been illustrated and described in detail in the drawings and foregoing description, the same should be considered as illustrative and not restrictive in character. It is understood that only the preferred embodiments have been presented and that all changes, modifications and further applications that come within the spirit of the disclosure are desired to be protected.

1. A flow battery system comprising:
a flow cell including a negative electrode, a separator, and a positive electrode;
a reservoir operably connected to the positive electrode and including an aqueous electrolyte;
a first sensor configured to generate a current signal indicative of an amplitude of a current passing into or out of the flow cell;
a second sensor configured to generate a voltage signal indicative of an output voltage across the flow cell;
a memory in which command instructions are stored;
a model of the flow cell stored within the memory; and
a processor configured to execute the command instructions to
obtain the current signal and the voltage signal,
estimate a state of charge (SOC) of the flow cell using the obtained current signal,
compute a model voltage of the flow cell using the obtained current signal, the obtained voltage signal, and the model,
compare the model voltage with the obtained voltage signal,
calculate a voltage error based upon the comparison of the model voltage with the obtained voltage signal, and
correct the estimated SOC based upon the voltage error.

2. The flow battery system of claim 1, wherein the model includes a representation of the bulk concentration of active species in the aqueous electrolyte in the form of the following equation:
$$\frac{d x}{d t} = η ( u , T ) \frac{u}{{C}_{0}} ,$$
wherein the bulk concentrations are a monotonic function of the actual SOC ‘x’, ‘C₀’ is the nominal capacity, ‘u’ is an applied current, and η is the coulombic efficiency.

3. The flow battery system of claim 2, wherein the model voltage “V_{cell}” is determined using the following equation:
$${V}_{cell} = {U}_{ocv} + k ln ( \frac{x}{{x}_{ref}} ) + {uR}_{tot} ( x , u , T , N ) ,$$
wherein “V_{cell}” is the model voltage,
“U_{OCV}” is a constant open circuit voltage (OCV) measured at a reference concentration of active species in the aqueous electrolyte,
“k” is related to the slope of OCV with respect to SOC,
“x_{ref}” is a reference SOC,
“Rₜₒₜ” is a total modelled impedance,
“T” is the temperature of the electrolyte, and
“N” is the flow rate of the aqueous electrolyte.

4. The flow battery system of claim 3, wherein:
the OCV of the flow battery system does not change significantly with actual SOC; and
the modeled Rₜₒₜ is defined by the following equations:
$$\frac{d {\hat{R}}_{tot}}{d t} = - pu ( {\hat{V}}_{cell} - {U}_{OCV} + u {\hat{R}}_{tot} ) , \\ \frac{d p}{d t} = β p - {p}^{2} {u}^{2} ,$$
where \hat{V}_{cell} is the measured voltage, U_{OCV} is the known open-circuit voltage and p is a positive number.

5. The flow battery system of claim 4, wherein the model voltage is determined using the following equation:
\hat{x}=ƒ(\hat{R}ₜₒₜ,u,T,N)
wherein “ƒ” is a known function in the model.

6. The flow battery system of claim 3, wherein:
the impedance of the flow battery system does not vary significantly with respect to actual SOC; and
the voltage error is calculated using the following equation:
$$\frac{d \hat{x}}{d t} = η ( u , T ) \frac{u}{{C}_{0}} + L ( {V}_{cell} - {\hat{V}}_{cell} ) .$$
where L>0 is a constant gain, \hat{x} represents the estimated SOC and \hat{V}_{cell} is the model output.

7. The flow battery system of claim 3, wherein:
both OCV and impedance are functions of actual SOC; and
the voltage error is calculated using the following equation:
$$\frac{d \hat{x}}{d t} = η ( u , y ) \frac{u}{{C}_{0}} + L ( {V}_{cell} - {\hat{V}}_{cell} ) , \\ where$$
$$L = \{ \begin{matrix}0 & if u > 0 , \\ {L}_{0} & if u \leq 0 ,\end{matrix}$$
and L0>0.

8. A method of correcting an estimated state of charge (SOC) of a flow battery system comprising:
obtaining a current signal indicative of an amplitude of a current passing into or out of the flow cell;
obtaining a voltage signal indicative of an output voltage across the flow cell;
estimating with a processor a state of charge (SOC) of the flow cell using the obtained current signal;
computing with the processor a model voltage of the flow cell using the obtained current signal and the obtained voltage signal using a model stored in a memory;
comparing with the processor the model voltage and the obtained voltage signal;
calculating with the processor a voltage error based upon the comparison of the model voltage with the obtained voltage signal; and
correcting with the processor the estimated SOC based upon the voltage error.

9. The method of claim 8, wherein calculating a voltage error comprises calculating the voltage error using the following equation:
$$\frac{d x}{d t} = η ( u , T ) \frac{u}{{C}_{0}} ,$$
wherein a bulk concentration of active species in an aqueous electrolyte are a monotonic function of the actual SOC ‘x’, ‘C₀’ is the nominal capacity, V is an applied current, and η is the coulombic efficiency.

10. The method of claim 9, wherein the model voltage “V_{cell}” is determined using the following equation:
$${V}_{cell} = {U}_{ocv} + k ln ( \frac{x}{{x}_{ref}} ) + {uR}_{tot} ( x , u , T , N ) ,$$
wherein “V_{cell}” is the model voltage,
“U_{OCV}” is a constant open circuit voltage (OCV) measured at a reference concentration of active species in the aqueous electrolyte,
“k” is related to the slope of OCV with respect to SOC,
“x_{ref}” is a reference SOC,
“Rₜₒₜ” is a total modelled impedance,
“T” is the temperature of the electrolyte, and
“N” is the flow rate of the aqueous electrolyte.

11. The method of claim 10, wherein:
the OCV of the flow battery system does not change significantly with actual SOC; and
the modeled Rₜₒₜ is defined by the following equations:
$$\frac{d {\hat{R}}_{tot}}{d t} = - pu ( {\hat{V}}_{cell} - {U}_{OCV} + u {\hat{R}}_{tot} ) , \\ \frac{d p}{d t} = β p - {p}^{2} {u}^{2} ,$$
where \hat{V}_{cell} is the measured voltage, U_{OCV} is the known open-circuit voltage and p is a positive number.

12. The method of claim 11, wherein the model voltage is determined using the following equation:
\hat{x}=ƒ(\hat{R}ₜₒₜ,u,T,N)
wherein “ƒ” is a known function in the model.

13. The method of claim 10, wherein:
the impedance of the flow battery system does not vary significantly with respect to actual SOC; and
the voltage error is calculated using the following equation:
$$\frac{d \hat{x}}{d t} = η ( u , T ) \frac{u}{{C}_{0}} + L ( {V}_{cell} - {\hat{V}}_{cell} ) .$$
where L>0 is a constant gain, \hat{x} represents the estimated SOC and \hat{V}^{cell} is the model output.

14. The method of claim 10, wherein:
both OCV and impedance are functions of actual SOC; and
the voltage error is calculated using the following equation:
$$\frac{d \hat{x}}{d t} = η ( u , T ) \frac{u}{{C}_{0}} + L ( {V}_{cell} - {\hat{V}}_{cell} ) , \\ where$$
$$L = \{ \begin{matrix}0 & if u > 0 , \\ {L}_{0} & if u \leq 0 ,\end{matrix}$$
and L0>0.
